(19) United States
(12) Patent Application Publication
(10) Pub. No.: US 2004/0163598 A1
(43) Pub. Date: Aug. 26, 2004

(54) Method and apparatus for manufacturing optical fiber preform using MCVD with preheating process

(76) Inventors: Young-Ju Kang, Seoul (KR); Ki-Wan Jang, Seoul (KR); Jong-Cheol Park, Gyeonggi-Do (KR)

Correspondence Address: John F. Dolan, Fredrikson & Byron, P.A., 4000 Pillsbury Center, 200 South Sixth Street, Minneapolis, MN, 55402-1425, US

(21) Appl. No.: 10/785,338

(22) Filed: Feb. 24, 2004

(30) Foreign Application Priority Data
Feb. 26, 2003 (KR) 10-2003-000012132

(51) Int. Cl. C23C 16/00

(52) U.S. Cl. 118/724

(57) ABSTRACT

When an optical fiber preform is manufactured using MCVD (Modified Chemical Vapor Deposition), dehydration gas supplied into a tube on which soot particles are deposited is preheated at 600 to 1200° C. so that an internal temperature of the tube is kept over 500° C. in order to improve efficiency of the dehydration process for removing hydroxyl groups. At this time, a preheater for preheating is installed near a front end of the tube where the dehydration gas is introduced, or installed at a predetermined position of a gas supply line, or installed on a gas path in a main pillow. In addition, the preheater is capable of controlling thermal capacity, and a heatproof plate is installed around the preheater.

### BACKGROUND OF THE INVENTION

1. Field of the Invention

The present invention relates to manufacturing an optical fiber preform using MCVD (Modified Chemical Vapor Deposition).

2. Description of the Related Art

In order to manufacture an optical fiber using a conventional vapor deposition manner, there are representatively used three methods: Modified Chemical Vapor Deposition (MCVD), Outside Vapor Deposition (OVD) and Vapor Axial Deposition (VAD). These methods may manufacture extremely pure core and clad, but the optical fibers manufactured by the methods are vulnerable to hydroxyl groups (OH⁻). Hydroxyl groups are generated by an O₂13 H₂ burner which is a heat source satisfying a high temperature above 1000° C., or adulterated as impurities among deposition gas.

Such hydroxyl groups are bonded to silicon (Si) of the core or clad, and this Si—OH absorbs light in the wavelength range near 1385 nm, thereby resulting in that the wavelength range of 1200 to 1600 nm is partially not usable. Generally, the absorption loss should be less than 0.33 dB/km in order to use the wavelength range about 1385 nm.

In order to reduce the optical loss in the wavelength range about 1385 nm, OVD or VAD conducts a dehydration process for removing OH ions by heating the mixture gas including Cl₂ or chlorine for removing hydroxyl groups at about 1200° C. to form HCl after depositing silica particles in a soot state. However, MCVD shows limitation to execute the dehydration process since silica particles are deposited on the inner surface of a tube.

Referring to FIGS. 1 and 2, in a conventional MCVD, a tube 14 mainly made of SiO2 is rotated between pillows 12 of a lathe 10, and an oxygen-hydrogen torch 16 slowly moves from a source gas input portion to a source gas output portion below the tube 14 for react the reaction gas such as SiCl₄ and GeCl₄ with O₂ so that SiO₂ or GeO₂ is deposited on the inner surface of the tube 14 at an appropriate ratio to form core and clad 15. In other words, since SiO₂ or GeO₂ is deposited and sintered on the inner surface of the tube 14 at the same time while the torch 16 is moving, the dehydration process cannot be executed like OVD or VAD in the conventional MCVD and thus hydroxyl groups may not effectively removed.

As mentioned above, in the conventional MCVD, hydroxyl groups may be penetrated into the tube 14 due to the oxygen-hydrogen torch 16, thereby causing increase of optical loss due to the hydroxyl groups. To prevent this increase of optical loss, there have been tried several attempts, i.e., by exchanging the oxygen-hydrogen torch 16 with a non-contaminating heat source such as a plasma heat source, or by forming a dispersion-resistant layer at a border of core and clad to reduce penetration of hydroxyl groups into the core. However, these attempts still cannot eliminate hydroxyl groups completely, and these attempts lead change of devices and processes, thereby disadvantageously increasing production time and cost.

### SUMMARY OF THE INVENTION

The present invention is designed to solve the problems of the prior art, and therefore it is an object of the present invention to provide method and apparatus for manufacturing an optical fiber preform which is capable of efficiently eliminating hydroxyl groups in MCVD (Modified Chemical Vapor Deposition).

In order to accomplish the above object, a method for manufacturing an optical fiber preform using MCVD divides the conventional deposition process into soot particle deposition, dehydration and sintering processes, and preheats dehydration gas or reaction gas supplied into a hollow tube at an appropriate temperature during each divided process.

In one aspect of the present invention, there is provided a method for manufacturing an optical fiber preform using MCVD (Modified Chemical Vapor Deposition), which includes a deposition process for depositing soot particles on an inner wall of a hollow tube; and a dehydration process for eliminating hydroxyl groups from the inner wall of the tube by supplying dehydration gas into the tube on which the soot particles have been deposited, wherein the dehydration gas supplied in the dehydration process is preheated at a temperature of 600 to 1200° C. so that a temperature in the tube is kept above 500° C.

Preferably, the dehydration gas is preheated at a position near a front end of the tube where the dehydration gas is introduced into the tube, or preheated at a position on a gas supply line before the dehydration gas is supplied to the tube, or at a position in a pillow of a lathe to which the tube is rotatably installed and in which a gas path of the dehydration gas supplied from an external gas supply line to the tube is formed.

At this time, the dehydration gas is preferably preheated with the use of a preheater capable of controlling thermal capacity.

In addition, it is preferred that a heatproof plate is installed near the preheater so as to protect environmental instruments from heat of the preheater.

In another aspect of the invention, there is also provided a method for manufacturing an optical fiber preform using MCVD, which includes the step of heating a tube with the use of a torch which moves along the tube with introducing a predetermined gas into the tube rotatably installed between a main pillow and an end pillow of a lathe, wherein the predetermined gas supplied into the tube is preheated at a temperature identical to or lower than a heating temperature of the moving torch.

Preferably, the heating step is a deposition process for depositing soot particles on an inner wall of the tube by introducing reaction gas into the tube, and the reaction gas is preheated before being introduced into the tube so as to keep a temperature in the tube over 500° C.

As another example, it is possible that the heating step is a sintering process for sintering soot particles deposited on an inner wall of the tube, and preheated dehydration gas is supplied into the tube so as to keep a temperature in the tube over 500° C.

At this time, the gas supplied into the tube is preheated at a position near a front end of the tube where the gas is introduced into the tube, or at a position on a gas supply line for supplying the gas into the tube, or alternatively at a predetermined position in the main pillow of the lathe to which the tube is rotatably installed and in which a gas path of the gas supplied from an external gas supply line to the tube is formed.

In still another aspect of the invention, there is also provided an apparatus for manufacturing an optical fiber preform using MCVD, which includes a lathe; main and end pillows installed to the lathe with a predetermined space for supporting a hollow tube rotatably therebetween; a torch for heating the tube below the tube with reciprocating from one end to the other end of the tube; a gas supply line installed to the main pillow and communicated with the tube through the main pillow for introducing gas into the tube from outside; a gas discharge line installed to the end pillow for discharging gas in the tube outward; and a preheater for preheating the gas to be supplied into the tube.

Preferably, the preheater is installed at a position near the front end of the tube where the gas is introduced into the tube, and a heatproof plate is installed between the preheater and the main pillow so as to protect the main pillow from heat of the preheater.

Alternatively, it is possible that the preheater is installed at a predetermined position on the gas supply line, and a heatproof plate is installed between the preheater and the main pillow so as to protect the main pillow from heat of the preheater.

As another alternative, it is also possible that the preheater is installed on a gas path inside the main pillow, and the gas path inside the main pillow is made of heat-resistant material.

At this time, the preheater is preferably capable of controlling thermal capacity.

### BRIEF DESCRIPTION OF THE DRAWINGS

Other objects and aspects of the present invention will become apparent from the following description of embodiments with reference to the accompanying drawing in which:

FIG. 1 is a schematic view showing an apparatus for manufacturing an optical fiber preform using a conventional MCVD;

FIG. 2 is an enlarged view for illustrating a deposition process executed by the apparatus of FIG. 1;

FIG. 3 is a diagram for illustrating a sooting process, when the deposition process executed by the apparatus of FIG. 1 is subdivided into a sooting process, a dehydration process and a sintering process;

FIG. 4 is a diagram for illustrating a dehydration process, when the deposition process executed by the apparatus of FIG. 1 is subdivided into a sooting process, a dehydration process and a sintering process;

FIG. 5 is a diagram for illustrating a sintering process, when the deposition process executed by the apparatus of FIG. 1 is subdivided into a sooting process, a dehydration process and a sintering process;

FIG. 6 is a graph showing temperature distribution of the tube outer wall according to the position of a torch in the dehydration process of FIG. 4;

FIGS. 7a to 7d are diagrams for illustrating formation of re-contaminatable region in the processes of FIGS. 3 to 5;

FIG. 8 is a schematic view showing an apparatus for manufacturing an optical fiber preform using MCVD according to a preferred embodiment of the present invention;

FIG. 9 is a graph showing temperature distribution on the tube outer wall according to the position of torch in the dehydration process of MCVD executed by the apparatus of FIG. 8;

FIG. 10 is a schematic view showing an apparatus for manufacturing an optical fiber preform using MCVD according to another preferred embodiment of the present invention;

FIG. 11 is a schematic view showing an apparatus for manufacturing an optical fiber preform using MCVD according to still another preferred embodiment of the present invention; and

FIG. 12 is a graph showing optical losses according to wavelength ranges of the optical fiber manufactured by the method of the present invention.

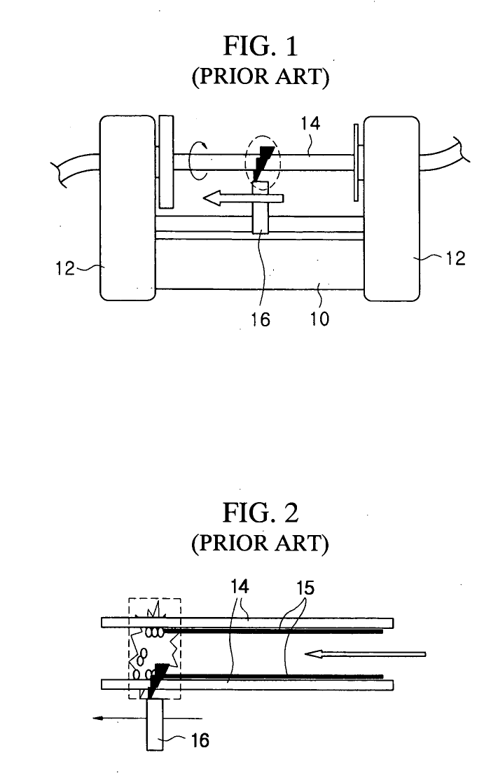

### DESCRIPTION OF THE PREFERRED EMBODIMENT

Hereinafter, preferred embodiments of the present invention will be described in detail referring to the accompanying drawings. Prior to the description, it should be understood that the terms used in the specification and appended claims should not be construed as limited to general and dictionary meanings, but interpreted based on the meanings and concepts corresponding to technical aspects of the present invention on the basis of the principle that the inventor is allowed to define terms appropriately for the best explanation. Therefore, the description proposed herein is just a preferable example for the purpose of illustrations only, not intended to limit the scope of the invention, so it should be understood that other equivalents and modifications could be made thereto without departing from the spirit and scope of the invention.

In the mean time, inventors of the present invention have been ever proposed a technique for dividing the conventional deposition process into sooting-dehydration-sintering processes and then conducting the dehydration process with using an oxygen-hydrogen torch so as to obtain an optical loss less than 0.33 dB/km at a wavelength of about 1385 nm in Korean Patent Application No. 10-2002-37360, not yet published at the priority date of this application.

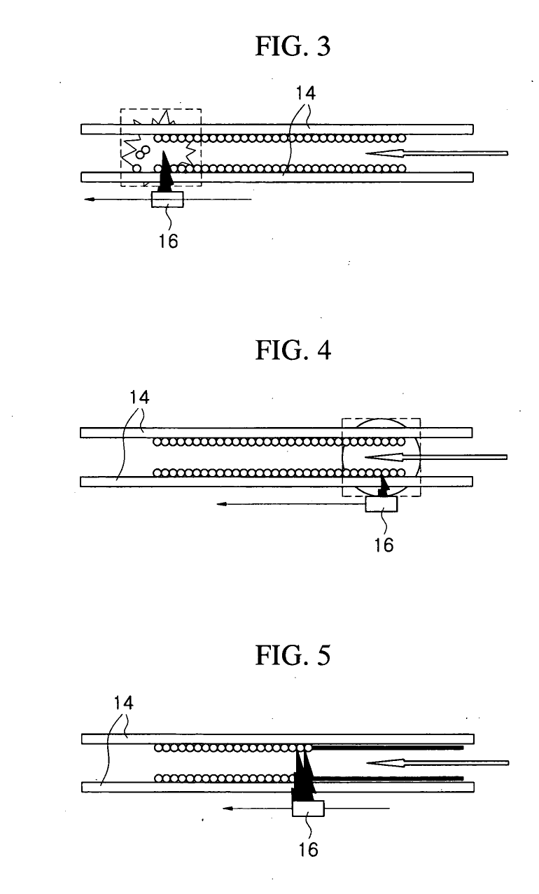

In the above application, a dehydration-oxidization process is applied to the conventional MCVD so as to add the dehydration process like the cases of OVD and VAD. The MCVD having an additional dehydration process proposed in the above application is now described in brief with reference to FIGS. 3 to 5.

First, as shown in FIG. 3, while large particles of SiO₂ are introduced into a tube 14 in a soot state, the tube is heated at a temperature of 1200 to 1600° C. with the use of a torch 16 so that soot is deposited on the inner wall of the tube 14.

After that, as shown in FIG. 4, dehydration gas such as chlorine, oxygen and helium is mixed at an appropriate ratio and introduced into the tube 14, and at the same time the tube 14 is heated at a temperature of 500 to 1300° C. with the use of the torch 16 to conduct the dehydration process. During the dehydration process, Si—OH existing in the tube 14 is reacted with Cl₂ and removed with generating HCl.

Then, as shown in FIG. 5, the tube 14 is heated at a temperature above 1700° C. with the use of the torch 16 to sinter the particles deposited on the inner wall of the tube 14.

These processes are repeated to make clad and core, and then the inner space of the tube 14 is eliminated through the collapse process.

The primary preform made through the above processes shows high OH concentration on its surface due to the use of OH burner, so the hydroxyl groups on the surface are removed by etching the surface with such as C₂F₆.

When the optical fiber preform is made using the conventional MCVD, the source of hydroxyl groups exists even in the gas introduced into the tube during the deposition process, in addition to the introduction of hydroxyl groups caused by the heat source, so the source of hydroxyl groups causes contamination in the tube 14 and thereby plays a role of increasing the optical loss due to hydroxyl group at a wavelength range of about 1385 nm.

However, in the aforementioned application, the dehydration process is conducted in order to solve such problems while one torch 16 is kinetically moving, differently from OVD or VAD. In other words, the technique proposed by the above application is different from OVD or VAD in which a preform is put into the sealed chamber with soot deposited thereon and then the preform is statically heated at a temperature of 1200 to 1300° C.

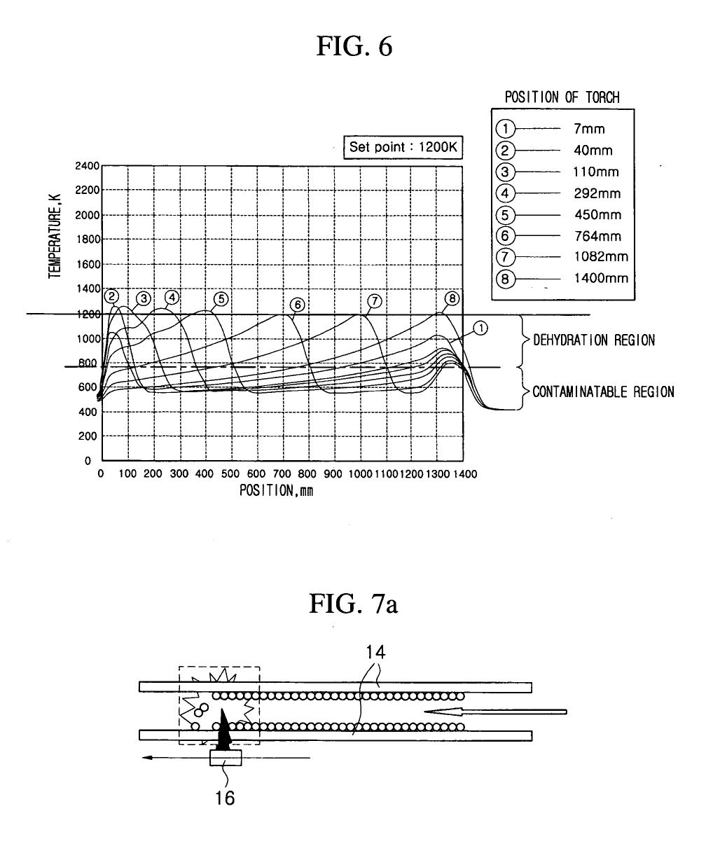

The graph of FIG. 6 shows temperature distribution on the outer wall of the tube 14 according to the position of the torch 16 in the dehydration process. The temperature in the tube 14 is shifted further rightward on the graph due to the flow in the tube 14.

As the torch 16 is moving toward the rear end of the tube 14, the front end of the tube 14 is gradually cooled below the dehydration temperature due to the effects of internal flow and external radiation. Thus, in case hydrogen (H) or hydroxyl group (OH) compound exists in the introduced dehydration gas at such region, the dehydrated region is apt to be contaminated again. In other words, considering that the effect of hydration reaction depends on temperature and time and SiO₂ has hydrophilic property, a region at a temperature below 500° C. may be contaminated by hydroxyl groups.

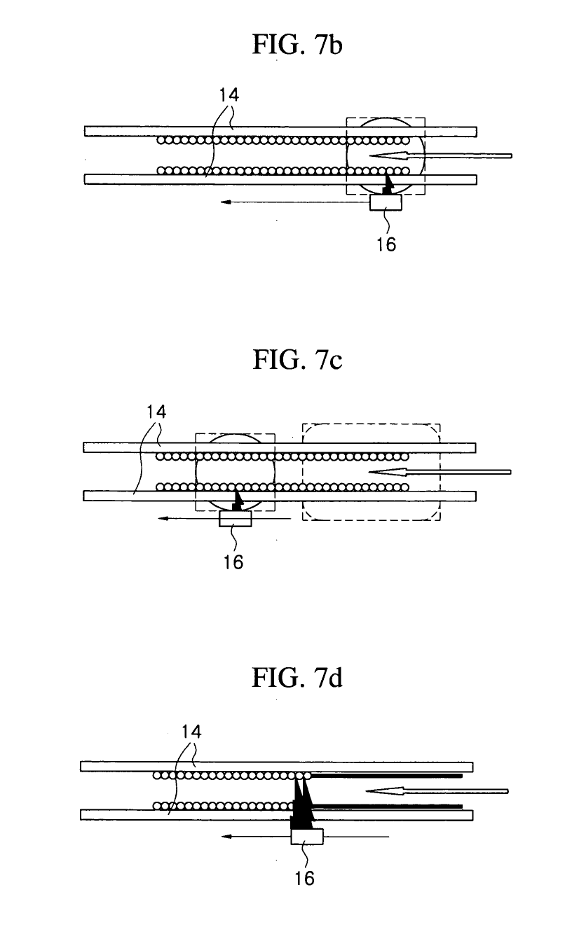

This phenomenon is schematically shown in FIGS. 7a to 7d. Referring to the figures, after reaction gas such as SiCl₄ and GeCl₄ is introduced into the tube 14 together with contaminative sources such as hydrogen (H) or hydroxyl group (OH) compound, the tube 14 is heated at a high temperature of 1200 to 1600° C. with the use of the torch 16 for the deposition process as shown in FIG. 7a. After that, as shown in FIGS. 7b and 7c subsequently, the tube 14 is heated at a temperature of 500 to 1300° C. for the dehydration process. However, though the front end of the tube 14 is heated at a temperature of 500 to 1300° C. at an initial stage of the dehydration process shown in FIG. 7b, the temperature at the front end of the tube 14 is dropped below 500° C. since there is no direct heat source near the front end at a later stage of the dehydration process (see FIG. 7c) when the torch 16 is moved to the rear end of the tube 14. Since contaminative sources such as hydrogen (H) or hydroxyl group (OH) compound are introduced into the tube 14 together with the dehydration gas such as He, Cl₂ and O₂ during the dehydration process, the front end of the tube 14 which is cooled below 500° C. is apt to be contaminated again (which is hereinafter called ‘a re-contaminatable region’). This re-contaminatable region is sintered together with the soot particles such as silica particles when the tube 14 is heated at a high temperature above 1700° C. with the use of the torch 16 during the sintering process shown in FIG. 7d, which is thus a factor of causing quality deterioration of the made optical fiber.

In addition, since the dehydration reaction mainly occurs at a high temperature region near the torch 16 in this MCVD, it is relatively difficult to control reaction efficiency rather than VAD or OVD in which the dehydration reaction occurs through overall region of the tube 14.

Thus, inventors have designed method and apparatus for more efficient dehydration in the modified MCVD which separately executes sooting, dehydration and sintering processes as mentioned above.

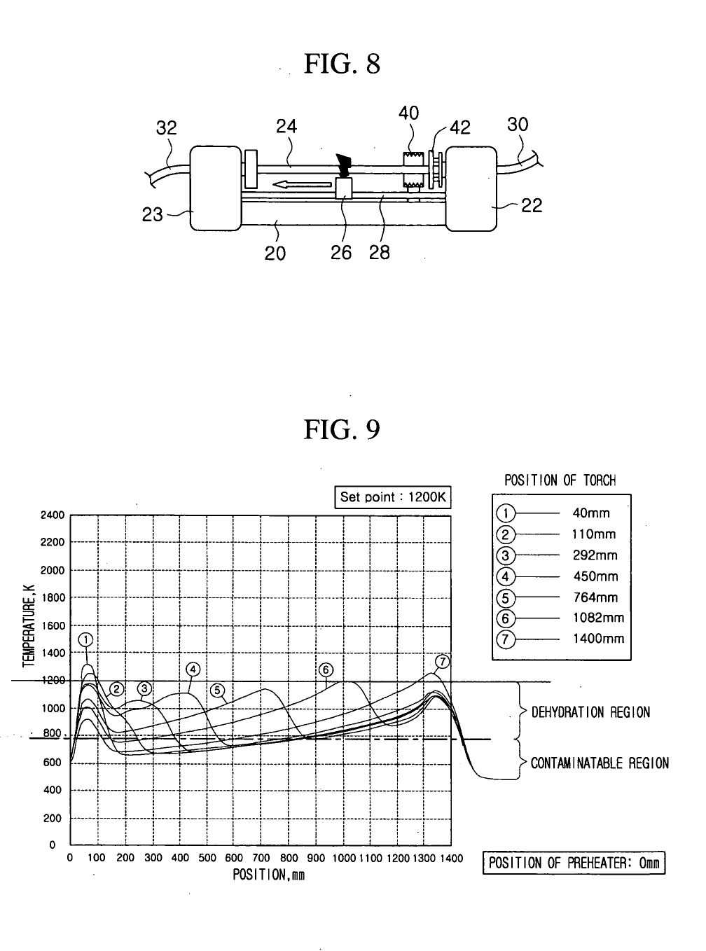

FIG. 8 shows an apparatus for manufacturing an optical fiber preform, which is used for the improved MCVD according to a preferred embodiment of the present invention.

Referring to FIG. 8, the optical fiber preform manufacturing apparatus of the present invention includes a lathe 20, which is the foundation of equipment. At both sides of the lathe 20, a main pillow 22 and an end pillow 23 are respectively installed. The main and end pillows 22 and 23 respectively have a predetermined height, and a cylindrical hollow tube 24 is installed between the pillows 22 and 23. The tube 24 is capable of rotating on its center between the main and end pillows 22 and 23.

The torch 26 is installed at a position near the tube 24, preferably below the tube 24. The torch 26 is also capable of heating the tube 24 with reciprocating from one end to the other end of the tube 24 along a torch transfer line 28 installed in parallel to the tube 24. In addition, the torch 26 is preferably capable of controlling thermal capacity in order to adjust heating temperature to the tube 24. The torch transfer line 28 is preferably fixed to the inner walls of the main and end pillows 22 and 23.

A gas supply line 30 for supplying gas into the tube 24 from outside is installed to the main pillow 22. The gas supply line 30 plays a role of supplying reaction gas such as SiCl₄ and GeCl₄ or dehydration gas such as He, Cl₂ and O₂ into the tube 24 through the main pillow 22. In addition, though not shown in the figure, it is possible to install a separate gas path in the main pillow 22 for interconnecting the tube 24 and the gas supply line 30.

A gas discharge line 32 is installed to the end pillow 23 in correspondence to the gas supply line 30. The gas discharge line 32 plays an act of discharging gas passing through the tube 24 to outside. In addition, it is possible to install a separate gas path (not shown) in the end pillow 23 for this purpose.

A preheater 40 is installed on the gas supply line through which gas is supplied into the tube 24. In this embodiment, the preheater 40 is installed at a position near the front end of the tube 24 where the gas is introduced into the tube 24. In other words, as shown in FIG. 8, the preheater 40 is configured so as to directly heat the tube 24 at a region near the main pillow 22.

Conventionally, an area near the front end of the tube 24 is a re-contaminatable region, of which temperature is dropped below 500° C. when the torch moves to the rear end of the tube during the dehydration process. However, the aforementioned preheater 40 plays a role of keeping the gas introduced into the tube 24 at an appropriate temperature by heating the region around the front end of the tube 24.

In addition, it is also possible to install a heatproof plate 42 between the preheater 40 and the main pillow 22. The heatproof plate 42 acts for preventing the heat of the preheater 40 from affecting on the main pillow 22 and its parts such as coupler or bearing for fixing the tube 24 to the main pillow 22. At this time, coolant may be circulated in the heatproof plate 42 so that the environmental instruments may be more effectively protected.

The preheater 40 may employ a chemical heat source such as an oxygen-hydrogen burner, or an electric heat source such as silica carbide or Zirconia. In addition, the preheater 40 is preferably configured so that a worker is capable of controlling thermal capacity as desired on consideration of work conditions and surroundings.

Now, the preheating process and its principle according to the present invention are described. The following preheating process is described based on the dehydration process of MCVD as a representative example.

For the dehydration process of MCVD, the tube 24 is heated by the torch 26 so that the inside of the tube 24 reaches a temperature of about 500 to 1500° C. while dehydration gas such as He, Cl₂ and O₂ is supplied into the tube 24 through the gas supply line 30. While heating the tube 24, the torch 26 is moved from one end to the other end of the tube 24 along the torch transfer line 28.

In addition, the preheater 40 preheats the dehydration gas introduced into the tube 24 at about 600 to 1200° C. at a position near the front end of the tube 24. In other words, the dehydration gas supplied into the tube 24 is previously heated up to a sufficiently high temperature by the preheater 40 before being heated by the torch 26. In particular, though the torch 26 moves to a position near the rear end of the tube 24, or near the end pillow 23, the preheater 40 continuously heats the front end of the tube 24 and the dehydration gas passing through the front end, thereby keeping the internal temperature of the overall tube 24 500° C. as a whole. Thus, the initial preheating of the preheater 40 increases temperature of the overall inside of the tube 24, and resultantly the dehydration reaction may continuously occur in the entire area of the tube 24.

Since the internal temperature of the tube 24 is increased on the whole owing to the above process, it is possible to prevent the conventional problem that the front region of the tube of which temperature is dropped below 500° C. is contaminated again by hydrogen (H) or hydroxyl group (OH) compound introduced into the tube 24 together with the dehydration gas. In addition, owing to this principle, the optical fiber preform manufacturing apparatus of the present invention may continuously react hydrogen (H) or hydroxyl group (OH) compound introduced from the front end of the tube 24 with chlorine (Cl) and eliminate them, so it is thus possible to stably manufacture an optical fiber of high quality, which shows an optical absorption loss less than 0.33 dB/km through the entire wavelength range of 1200 to 1600 nm.

FIG. 9 is a graph showing temperature distribution on the outer wall of the tube 24 according to the position of the torch 26 in the dehydration process including the preheating process according to the present invention. This graph shows experimental results conducted under the condition that the preheater 40 installed to the front end of the tube 24 acts as a heat source giving a temperature of 1200° C. Referring to this graph, it is easily noted that the internal temperature of the tube is increased as a whole, compared with the experimental results in case of not using the preheater (see FIG. 6). In particular, the region of which temperature is dropped below 500° C., which is a criterion of determining possibility of contamination, is dramatically reduced rather than the conventional case. This means that re-contamination due to hydrogen (H) or hydroxyl group (OH) compound is nearly eliminated or remarkably reduced in the dehydration process executed by the present invention.

In fact, in the dehydration process without using a preheater, the internal temperature of the tube is partially decreased even to 400° C., which becomes a factor of increasing an optical loss up to 0.4 dB/km. However, the present invention may reproductively manufacture an OH-free optical fiber capable of keeping an optical loss below 0.33 dB/km at the entire wavelength range of 1200 to 1600 nm, particularly at a wavelength of 1385 nm, since the front end of the tube, which has conventionally suffered from low temperature, may keep its temperature high owing to the preheater 40. Thus, the present invention enables mass production of an optical fiber capable of data transmission at the entire wavelength range of 1200 to 1600 nm in an easy way by simple installation change, so it is possible to dramatically improve quality and productivity of optical fibers.

Heretofore, the preheating process of the present invention is described on the basis of the dehydration process of MCVD as a representative example. However, the principle of the present invention is not limited to the dehydration process, but may be applied to other processes with the use of the same configuration. In particular, the preheating principle according to the present invention may give excellent effects when being applied to the deposition process and the sintering process of MCVD.

As an example, such preheating principle of the present invention is applied to the deposition process of MCVD as follows. For the deposition process, if the general configuration shown in FIG. 8 is applied as it is, reaction gas such as SiCl₄ and GeCl₄ is introduced into the tube 24 through the gas supply line 30, and the torch 26 moving along the tube 24 heats the tube 24 for reaction between the reaction gas and O₂, and thus the soot particles such as SiO₂ and GeO₂ are deposited on the inner wall of the tube 24 at an appropriate ratio. At this time, a heating temperature of the torch 26 is about 1200 to 1500° C.

In the aforementioned configuration, the preheater 40 of the present invention heats the front end region of the tube 24. At this time, a heating temperature of the preheater 40 is set same as or slightly lower than the heating temperature of the torch 26, preferably set at 600 to 1200° C., which is identical to the case of the above-mentioned dehydration process. Then, the internal temperature of the tube 24 may have more regular distribution as a whole, so it is possible to improve deposition efficiency of soot particles. In addition, since the preheater 40 makes the internal temperature of the tube 24 not be locally decreased below 500° C., the present invention may prevent the deposition layer of the soot particles from being contaminated by hydrogen (H) or hydroxyl group (OH) compound introduced into the tube 24 together with the reaction gas.

In addition, the preheating principle of the present invention may be applied to the sintering process of MCVD as follows. When the improved sintering process is described with the use of the general configuration shown in FIG. 8, while soot particles are deposited on the inner wall of the tube 24, the torch 26 moving along the tube 24 heats the tube 24 at about 1700° C. or above to sinter the deposited soot particles. At this time, dehydration gas such as He, Cl₂ and O₂ is supplied into the tube 24 through the gas supply line 30 so that sintering and dehydration are conducted at the same time.

The preheater 40 according to the present invention heats the dehydration gas introduced into the tube 24 at a predetermined temperature, preferably at 600 to 1200° C. identical to the case of the aforementioned dehydration process, before the dehydration gas is heated by the torch 26. Thus, the internal temperature of the tube 24 has more regular distribution owing to the preheater 40. Particularly, a region of which temperature is lowered below 500° C. is completely eliminated or dramatically reduced, so it is possible to prevent the soot particles during sintering from being contaminated by hydrogen (H) or hydroxyl group (OH) compound introduced into the tube 24 together with the dehydration gas.

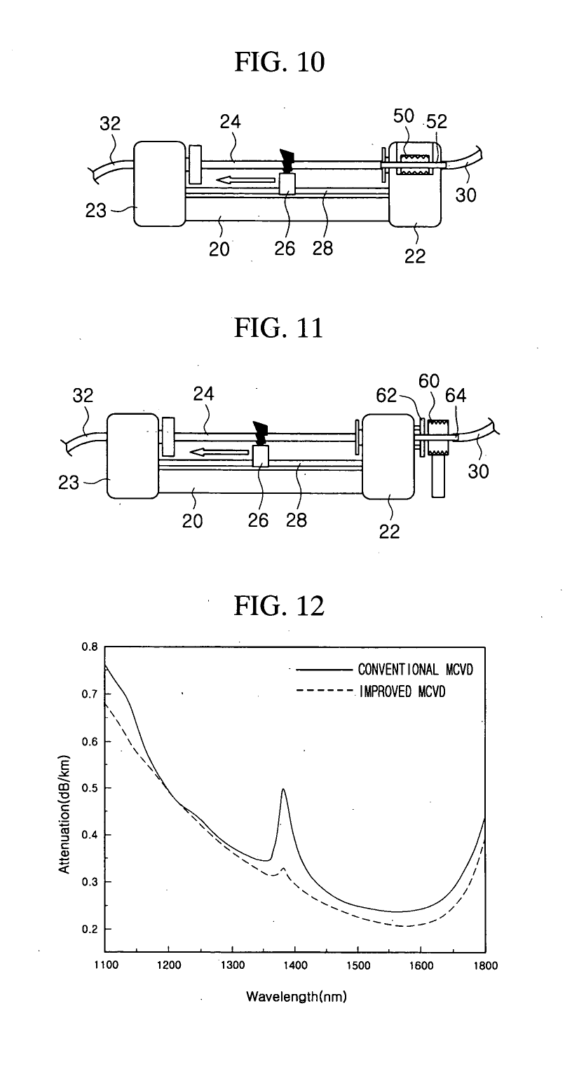

FIG. 10 shows an optical fiber preform manufacturing apparatus according to another embodiment of the present invention. This embodiment is substantially identical to the former embodiment, except that installed location and configuration of the preheater and relevant parts are different.

In this embodiment, the preheater 50 is installed inside the main pillow 22. Generally, the main pillow 22 rotatably combines one end of the tube 24 and is provided with a gas path 52 for communicating the gas supply line 30 with the inside of the tube 24. In the present embodiment, the preheater 50 is installed near the gas path 52 in the main pillow 22, and heats gas flowing through the gas path 52.

At this time, the gas path 52 in the main pillow 22 is preferably made of heat-resistant material in order to endure high temperature from the preheater 50.

The optical fiber preform manufacturing apparatus of this embodiment substantially gives the same principle and effects as the former embodiment in the points that the preheater is installed on a passage of the gas introduced into the tube 24, though the installation location of the preheater 50 is somewhat different from that of the former embodiment. In addition, the preheater of this embodiment may also show substantially identical results to the graph of FIG. 9 of course, when it is applied to the dehydration process of MCVD.

As still another embodiment of the present invention, a preheater may be installed on the gas supply line 30 positioned out of the main pillow 22, as shown in FIG. 11. In this case, the preheater 60 preheats gas passing through the gas supply line 30, and the gas is in advance heated to an appropriate temperature before introduced into the tube 24.

At this time, in order to avoid unnecessary heat loss, the preheater 60 is preferably located at a position nearest to the main pillow 22. In addition, in order to avoid damage of the main pillow 22 caused by the heat of the preheater 60, a heatproof plate 62 may be mounted between the preheater 60 and the main pillow 22. The heatproof plate 62 may also be configured so that coolant is circulated around the heatproof plate 62 so as to isolate heat transfer more effectively. Moreover, at a region where the preheater 60 is installed, the gas supply line 30 is preferably made of material having excellent thermal resistance in order to avoid damage due to the heat of the preheater 60. In addition, as shown in FIG. 11, it is also possible to additionally mount a separate pipe 64 at a position to which the preheater 60 is installed.

The optical fiber preform manufacturing apparatus of this embodiment substantially gives the same principle and effects as the former embodiments in the points that the preheater is installed on a passage of the gas introduced into the tube 24, though the installation location of the preheater 60 is somewhat different from that of the former embodiments. In addition, the preheater of this embodiment may also show substantially identical results to the graph of FIG. 9 of course, when it is applied to the dehydration process of MCVD.

An optical fiber manufactured by each embodiment of the present invention may show a low optical absorption loss in the entire wavelength range of 1200 to 1600 nm. In particular, it is possible to obtain an optical fiber of high quality which shows an optical absorption loss less than 0.33 dB/km at a wavelength of 1385 nm. A graph for illustrating optical losses of an optical fiber manufactured by the present invention at each wavelength is well shown in FIG. 12.

### Applicability to the Industry

According to the method and apparatus for manufacturing an optical fiber preform using MCVD of the present invention, the internal temperature of the tube may be more uniformly distributed during the dehydration process, so the dehydration reaction may occur through the whole length of the tube. In particular, the present invention restrains the internal temperature of the tube not to be lowered below 500° C., so it is possible to prevent the tube from being re-contaminated by impurities introduced together with dehydration gas.

In addition, according to the optical fiber preform manufacturing method and apparatus using MCVD of the present invention, hydrogen and hydroxyl groups may be more effectively eliminated since the internal temperature of the tube is always kept constant, so it is possible to lower the optical absorption loss in the entire wavelength range of 1200 to 1600 nm, and particularly give an optical fiber of high quality which shows an optical absorption loss less than 0.33 dB/km at a wavelength of 1385 nm.

Moreover, the optical fiber preform manufacturing apparatus of the present invention may be easily realized by simple structural changes, and advantageously show very high productivity by rapidly conducting a very efficient dehydration process with the use of a torch and a preheater.

Furthermore, the optical fiber preform manufacturing method and apparatus may be universally applied to the deposition process and the sintering process as well as the dehydration process of MCVD. In particular, when the present invention is applied to the deposition process of MCVD, it is possible to give an additional effect of improving deposition efficiency of soot particles.

The present invention has been described in detail. However, it should be understood that the detailed description and specific examples, while indicating preferred embodiments of the invention, are given by way of illustration only, since various changes and modifications within the spirit and scope of the invention will become apparent to those skilled in the art from this detailed description.

What is claimed is:

1. A method for manufacturing an optical fiber preform using MCVD (Modified Chemical Vapor Deposition), comprising:
a deposition process for depositing soot particles on an inner wall of a hollow tube; and
a dehydration process for eliminating hydroxyl groups from the inner wall of the tube by supplying dehydration gas into the tube on which the soot particles have been deposited,
wherein the dehydration gas supplied in the dehydration process is preheated at a temperature of 600 to 1200° C. so that a temperature in the tube is kept above 500° C.

2. A method for manufacturing an optical fiber preform using MCVD according to claim 1,
wherein the dehydration gas is preheated at a position near a front end of the tube where the dehydration gas is introduced into the tube.

3. A method for manufacturing an optical fiber preform using MCVD according to claim 1,
wherein the dehydration gas is preheated at a position on a gas supply line before the dehydration gas is supplied to the tube.

4. A method for manufacturing an optical fiber preform using MCVD according to claim 1,
wherein the dehydration gas is preheated at a position in a pillow of a lathe to which the tube is rotatably installed and in which a gas path of the dehydration gas supplied from an external gas supply line to the tube is formed.

5. A method for manufacturing an optical fiber preform using MCVD according to claim 1,
wherein the dehydration gas is preheated with the use of a preheater capable of controlling thermal capacity.

6. A method for manufacturing an optical fiber preform using MCVD according to claim 5,
wherein a heatproof plate is installed near the preheater so as to protect environmental instruments from heat of the preheater.

7. A method for manufacturing an optical fiber preform using MCVD, comprising the step of:
heating a tube with the use of a torch which moves along the tube with introducing a predetermined gas into the tube rotatably installed between a main pillow and an end pillow of a lathe,
wherein the predetermined gas supplied into the tube is preheated at a temperature identical to or lower than a heating temperature of the moving torch.

8. A method for manufacturing an optical fiber preform using MCVD according to claim 7,
wherein the heating step is a deposition process for depositing soot particles on an inner wall of the tube by introducing reaction gas into the tube,
wherein the reaction gas is preheated before being introduced into the tube so as to keep a temperature in the tube over 500° C.

9. A method for manufacturing an optical fiber preform using MCVD according to claim 7,
wherein the heating step is a sintering process for sintering soot particles deposited on an inner wall of the tube,
wherein preheated dehydration gas is supplied into the tube so as to keep a temperature in the tube over 500° C.

10. A method for manufacturing an optical fiber preform using MCVD according to claim 7,
wherein the gas supplied into the tube is preheated at a position near a front end of the tube where the gas is introduced into the tube.

11. A method for manufacturing an optical fiber preform using MCVD according to claim 10,
wherein the gas is preheated with the use of a preheater capable of controlling thermal capacity.

12. A method for manufacturing an optical fiber preform using MCVD according to claim 11,
wherein a heatproof plate is installed near the preheater so as to protect environmental instruments from heat of the preheater.

13. A method for manufacturing an optical fiber preform using MCVD according to claim 7,
wherein the gas supplied into the tube is preheated at a position on a gas supply line for supplying the gas into the tube.

14. A method for manufacturing an optical fiber preform using MCVD according to claim 13,
wherein the gas is preheated with the use of a preheater, and the preheater is capable of controlling thermal capacity.

15. A method for manufacturing an optical fiber preform using MCVD according to claim 14,
wherein a heatproof plate is installed near the preheater so as to protect environmental instruments from heat of the preheater.

16. A method for manufacturing an optical fiber preform using MCVD according to claim 7,
wherein the gas supplied into the tube is preheated at a predetermined position in the main pillow of the lathe to which the tube is rotatably installed and in which a gas path of the gas supplied from an external gas supply line to the tube is formed.

17. A method for manufacturing an optical fiber preform using MCVD according to claim 16,
wherein the gas supplied into the tube is preheated with the use of a preheater, and the preheater is capable of controlling thermal capacity.

18. An apparatus for manufacturing an optical fiber preform using MCVD, comprising:
a lathe;
main and end pillows installed to the lathe with a predetermined space for supporting a hollow tube rotatably therebetween;
a torch for heating the tube below the tube with reciprocating from one end to the other end of the tube;
a gas supply line installed to the main pillow and communicated with the tube through the main pillow for introducing gas into the tube from outside;
a gas discharge line installed to the end pillow for discharging gas in the tube outward; and
a preheater for preheating the gas to be supplied into the tube.

19. An apparatus for manufacturing an optical fiber preform using MCVD according to claim 18,
wherein the preheater is installed at a position near the front end of the tube where the gas is introduced into the tube.

20. An apparatus for manufacturing an optical fiber preform using MCVD according to claim 19,
wherein a heatproof plate is installed between the preheater and the main pillow so as to protect the main pillow from heat of the preheater.

21. An apparatus for manufacturing an optical fiber preform using MCVD according to claim 18,
wherein the preheater is installed at a predetermined position on the gas supply line.

22. An apparatus for manufacturing an optical fiber preform using MCVD according to claim 21,
wherein a heatproof plate is installed between the preheater and the main pillow so as to protect the main pillow from heat of the preheater.

23. An apparatus for manufacturing an optical fiber preform using MCVD according to claim 18,
wherein the preheater is installed on a gas path inside the main pillow.

24. An apparatus for manufacturing an optical fiber preform using MCVD according to claim 23,
wherein the gas path inside the main pillow is made of heat-resistant material.

25. An apparatus for manufacturing an optical fiber preform using MCVD according to claim 18,
wherein the preheater is capable of controlling thermal capacity.
